(19) United States
(12) Patent Application Publication
(10) Pub. No.: US 2010/0314699 A1
(43) Pub. Date: Dec. 16, 2010

(54) ELECTROCHEMICAL SENSOR DEVICE, METHOD OF MANUFACTURING THE SAME

(75) Inventors: Mohammed Meftah, Tilburg (NL); Franciscus Petrus Widdershoven, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/517,858

(22) PCT Filed: Dec. 7, 2007
(86) PCT No.: PCT/IB2007/054972

§ 371 Date: Jun. 5, 2009

(30) Foreign Application Priority Data
Dec. 12, 2006 (EP) 06125903.2

(51) Int. Cl. H01L 29/66; H01L 21/50

(52) U.S. Cl. 257/414; 438/49; 257/E29.166; 257/E21.499

(57) ABSTRACT

An electrochemical sensor device (100) for analysing a sample, the device (100) comprising an electronic chip (101) comprising a sensor portion (102) being sensitive for particles of the sample, a carrier element (103, 104) bonded to the electronic chip (101) to define a fluidic path together with the electronic chip (101), and a counter electrode (105) provided in a surface portion of the carrier element (103, 104).

### FIELD OF THE INVENTION

The invention relates to an electrochemical sensor device.

Beyond this, the invention relates to sensor array for analysing a sample.

Moreover, the invention relates to a method of manufacturing an electrochemical sensor device.

### BACKGROUND OF THE INVENTION

A biosensor may be a device for the detection of an analyte that combines a biological component with a physicochemical or physical detector component.

In electrochemical sensors, an electrical connection with the electrolyte is made by means of a so-called counter electrode. On-chip integration of such an electrode is not trivial because the required electrode material is not compatible with that used in a standard CMOS process. The electrode material should have the property that the electrochemical reactions taking place at its interface with the electrolyte are reversible. In typical biological electrolytes like blood plasma, where chlorine ions are the dominant anion species, an Ag/AgCl (silver/silver-chloride) electrode is commonly used as a counter electrode. The corresponding reaction is

Ag+Cl⁻ [symbol] AgCl+e⁻

This reaction is reversible provided that metallic silver as well as (insolvable) silver-chloride are simultaneously present and in contact with the electrolyte. The most common way to get a silver/silver-chloride electrode integrated on-chip is by means of electroplating followed by chlorination of the silver surface.

However, for electroplating it is necessary to excite an electrochemical reaction in which an electrical potential has to be applied to the electrode. This implies that this process cannot be carried out on wafer level, but only when the chip is packaged. This extra process step is costly and therefore not attractive.

Electroless silver deposition, an alternative to electroplating, is hard to control and therefore less useful.

Conventional systems are disclosed in A. Simonis, H. Lüth, J. Wang, M. J. Schöoning, “Strategies of Miniaturised Reference Electrodes Integrated in a Silicon Based “one chip” pH Sensor”, Sensors (ISSN 1424-8220), July 2003 and in http://www.imec.be/wwwinter/microsystems/biosensors/multiparam.shtml.

A widely used method for bringing a counter electrode into contact with the electrolyte is by means of using an off-chip counter electrode. In this case electroplating can be performed much more easily. However, a disadvantage of this method is that the electrode cannot be easily correctly alignment in the electrolyte during the packaging process of the electrochemical sensor. Accurate alignment steps that exist are expensive and are therefore not attractive for the production of electrochemical sensors in high-volume with minimal investments.

Thus, the manufacture of counter electrodes for conventional electrochemical sensors may be expensive.

### OBJECT AND SUMMARY OF THE INVENTION

It is an object of the invention to provide an electrode for an electrochemical sensor which can be manufactured in a cheap manner.

In order to achieve the object defined above, an electrochemical sensor device, a sensor array, and a method of manufacturing an electrochemical sensor device according to the independent claims are provided.

According to an exemplary embodiment of the invention, an electrochemical sensor device for analysing a sample is provided, the device comprising an electronic chip comprising a sensor portion being sensitive for particles of the sample, a carrier element bonded to the electronic chip to define a fluidic path together with the electronic chip, and a counter electrode provided in a surface portion of the carrier element.

According to another exemplary embodiment of the invention, a sensor array for analysing a sample is provided, the sensor array comprising a plurality of electrochemical sensor devices having the above mentioned features.

According to still another exemplary embodiment of the invention, a method of manufacturing an electrochemical sensor device for analysing a sample is provided, the method comprising providing an electronic chip comprising a sensor portion being sensitive for particles of the sample, bonding a carrier element to the electronic chip to define a fluidic path together with the electronic chip, and providing a counter electrode in a surface portion of the carrier element.

In the context of this application, the term “sample” may particularly denote any solid, liquid or gaseous substance to be analysed, or a combination thereof. For instance, the substance may be a liquid or suspension, furthermore particularly a biological substance. Such a substance may comprise proteins, polypeptides, nucleic acids, lipids, carbohydrates, cells, etc. The sample may be a fluidic sample conducted through a fluidic path of the device.

The term “electrochemical sensor device” may particularly denote any sensor device capable of detecting the presence of particles by electrochemical procedures. Thus, such a sensor device may include electrical components in functional cooperation with chemical components. Particularly, chemical modifications in response to a sensor event may be detected electrically.

The term “electronic chip” may particularly denote a semiconductor chip having electronic circuitry monolithically integrated therein. Such an electronic chip may be manufactured in silicon technology, or with any other group IV semiconductor (like germanium), or may be manufactured in group III-group V technology (for instance gallium arsenide).

The term “sensor portion” may particularly denote an active portion of an electronic chip at which the specific sensor events take place. At such a sensor portion, for instance, capture molecules may be immobilized in order to enable hybridization events with complementary particles, for example complementary DNA molecules.

The term “carrier element” may particularly denote any mechanical support element which allows to fasten or attach the electronic chip to the well. Such a carrier element may, for instance, define a fluidic path through which a fluidic sample may flow. The carrier element may be made of any suitable material, like glass, plastics, or a semiconductor.

The term “bonded” may particularly denote any mechanical connection between the carrier element and the electronic chip, for instance soldering, adhering, gluing, a click connection, etc. The term bonding may particularly denote the attachment of an IC chip to a substrate.

The term “fluidic path” may particularly denote a channel or any fluid conduit through which a fluid, that is to say any gas or liquid or gas-liquid mixture, optionally comprising solid particles, may be moved.

According to an exemplary embodiment of the invention, an electrochemical sensor may be provided at which a counter electrode is not provided on an electronic chip, but on a carrier element bonded to the electronic chip. This may allow for producing a self-aligned and therefore accurately positioned counter electrode being manufacturable with significantly reduced effort. Particularly, typical materials for counter electrodes, for instance silver-chloride, are not compatible with CMOS technology so that a manufacture in accordance with the electronic chip may be expensive and difficult. Such a counter electrode may be used in an electrochemical sensor for modulating signals in contact with an electrolyte. It may be easily possible to manufacture such a counter electrode at a carrier element.

Therefore, according to an exemplary embodiment, a self-aligned counter electrode for electrochemical sensors may be provided. An off-chip self-aligned counter electrode for electrochemical sensors may be automatically correctly aligned in a fluidic path without the need of an extra process step when the electrochemical chip is bonded on this carrier, for instance a Moulded Interconnection Device (MID). This may finally result in a much cheaper electrochemical sensor solution.

According to an exemplary embodiment, a sensor device may be provided which can be used for any kind of electrochemical sensors. For example, a single molecule biosensor (see below) may be used as an example. In a single molecule biosensor, a magnetic biosensor package (as disclosed, for instance, in A. J. M. Nellissen et al (2005) “A new package for silicon biosensors”, EMPC 2005, June 12-15, Brugge, Belgium) may be reconfigured and reconstructed for use as an electrochemical sensor. Instead of a magnetic biochip, a single molecule biochip may then be provided with its active area in the middle of the chip. Copper tracks (provided, for instance, at a lower surface of the MID carrier element to enable transport of electrical signals from an electronic chip to an exterior analysis unit) may be gold-plated to get a sufficient chip bonding.

During the packaging process of an electrochemical sensor, the alignment of an off-chip counter electrode may be an issue. Extra process steps may be conventionally required which may make the production of electrochemical sensors expensive. An off-chip self-aligned counter electrode provided by exemplary embodiments of the invention may be an appropriate solution for electrochemical sensors.

When the electrochemical chip is bonded on its carrier during packaging, the counter electrode is automatically correctly aligned in the fluidics without the need of an extra process step. The solution may be very attractive for the production of electrochemical sensors and high volume with minimal investments.

Next, further exemplary embodiments of the electrochemical sensor device will be explained. However, these embodiments also apply to the sensor array and to the method of manufacturing an electrochemical sensor device.

The carrier element may comprise a well member, particularly a Molded Interconnection Device (MID), comprising a well, wherein the sensor portion may be located adjacent to a bottom portion of the well member. Such a well may be a tapering through hole formed in a substrate. The MID technology may therefore be adapted to the field of electrochemical sensors and may assist in efficiently designing a counter electrode.

The carrier element may comprise a cover member, particularly a fluidic package part, arranged relative to the well member to define an inlet and an outlet of the fluidic path between the cover member and the well member. The cover member which may be realized as a fluidic package part, may contribute to the spatial definition of a fluid flow path. Particularly, channels or other sample transporting conduits may be formed on and/or in the cover member.

A sample flow barrier may be provided between the well member and the electronic chip. Such a flow barrier may be manufactured of SU8 material and may allow to disconnect a sample space from an electronic portion of the device. SU8 is a photoresist based on epoxies.

The well member may be bonded to the electronic chip. Such a bonding may be performed, for example, by an electrically conductive bump such as a gold bump. Such a gold bump may serve simultaneously for attaching the carrier element to the electronic chip and for conducting electrical signals from the electronic chip device to an exterior control unit, or in the opposite direction.

The device may comprise an electrically conductive track provided on a lower surface (that is a surface opposing a sample chamber) of the well member. This electrically conductive track may be electrically coupled to the metal bump, and the metal bump may be coupled to electric contacts of the electronic chip device to thereby allow for an electric signal transport path.

The counter electrode may be accommodated in the well. By positioning the counter electrode in the well, the barrier-like geometrical configuration of the counter electrode may contribute to the definition of a fluid flow path, that is to say a path along which a fluidic sample may flow, thereby ensuring that the counter electrode is functionally coupled with the electrolytic sample. This may allow the counter electrode to fulfill its function properly and to simultaneously define a fluid flow conduit.

A spacer or bridge element may be provided as a part of the well member (which may be a MID), may be positioned adjacent (i.e. in direct contact without the need of an adhering connection) to the cover element, and may extend in the well towards the electronic chip. The counter electrode may be formed at an end portion of the bridge element (located closest to the electronic chip) to define the fluidic path between the counter electrode and the sensor portion of the electronic chip opposing the counter electrode. For example, an upper surface of the bridge element may abut against the fluidic package part and a lower surface thereof may extend into the well and may bridge a relatively large distance spacing these two elements. At an end portion, for example at a tip of the bridge element, a silver/silver-chloride counter electrode may be provided to define a relatively narrow fluid path around the active sensor part.

The counter electrode may be accommodated at a surface delimiting an inlet and/or an outlet of the fluidic path. The inlet and the outlet of the fluidic path may also be relatively narrow channels in which a layer of counter electrode material may be located to ensure that the sample having electrolytic properties is brought in interaction with the counter electrode. This may allow to have an efficient counter electrode geometry and an accurate sensor.

The counter electrode may further be connected to an upper surface of the well member and/or a lower surface of the cover element in the inlet and/or in the outlet of the fluidic path. This may be a very efficient and cheap configuration of the counter electrode.

According to an exemplary embodiment, the counter electrode may be arranged off-chip, that is to say apart from the electronic chip. Therefore, the counter electrode may be out of contact with the electronic chip device and may be manufactured in another manufacturing procedure as compared to the electronic chip manufacture. This may allow to prevent the need to introduce materials like AgCl (which may be used appropriately as a counter electrode) in a CMOS process for manufacturing the electronic chip.

The sensor portion may be a capacitive sensor portion, and may particularly comprise electric circuitry integrated in the electronic chip, a working electrode provided on the electric circuitry, and a self-assembled monolayer provided on the working electrode. In other words, a change in the capacitance of the sensor portion may be used to detect a sensor event. For this purpose, it is for instance possible that a particle to be detected may cause a hybridization with capture molecules immobilized on a surface of a working electrode. This may change the electric (for instance capacitive) properties in the environment of the working electrode and may result in a signal detectable by a connected electric circuitry, for instance a MOSFET. The working electrode may be connected to the gate electrode of the MOSFET, thereby ensuring that the conductivity of the MOSFET is modulated by the sensor event. As an alternative to a capacitive detection principle, an inductive or ohmic measurement may be carried out.

The device may be used as a sensor device, particularly a biosensor device, a biochip, a lab-on-chip, an electrophoresis device, a sample transport device, a sample mix device, a cell lysing device, a sample washing device, a sample purification device, a polymerase chain reaction (PCR) device and a hybridization analysis device. Therefore, the device may be appropriately used in any fields of life science, particularly in the context of an electrochemical detection.

The aspects defined above and further aspects of the invention are apparent from the examples of embodiment to be described hereinafter and are explained with reference to these examples of embodiment.

### BRIEF DESCRIPTION OF THE DRAWINGS

The invention will be described in more detail hereinafter with reference to examples of embodiment but to which the invention is not limited.

FIG. 1 illustrates a device according to an exemplary embodiment of the invention.

FIG. 2 illustrates a conventional biosensor package.

FIG. 3 shows a MID track layout of the biosensor package of FIG. 2.

FIG. 4 shows a biosensor package according to an exemplary embodiment of the invention.

FIG. 5 shows a MID track layout of the biosensor package of FIG. 4.

FIG. 6 to FIG. 8 show biosensor packages according to exemplary embodiments of the invention.

FIG. 9 to FIG. 11 illustrate a detection principle of a capacitive biosensor according to an exemplary embodiment of the invention in different operation modes.

FIG. 12 shows a detailed view of a sensor element of a device according to an exemplary embodiment of the invention.

FIG. 13 shows an equivalent circuit diagram of the sensor element of FIG. 12.

FIG. 14 illustrates a device according to an exemplary embodiment of the invention.

### DESCRIPTION OF EMBODIMENTS

The illustration in the drawing is schematically. In different drawings, similar or identical elements are provided with the same reference signs.

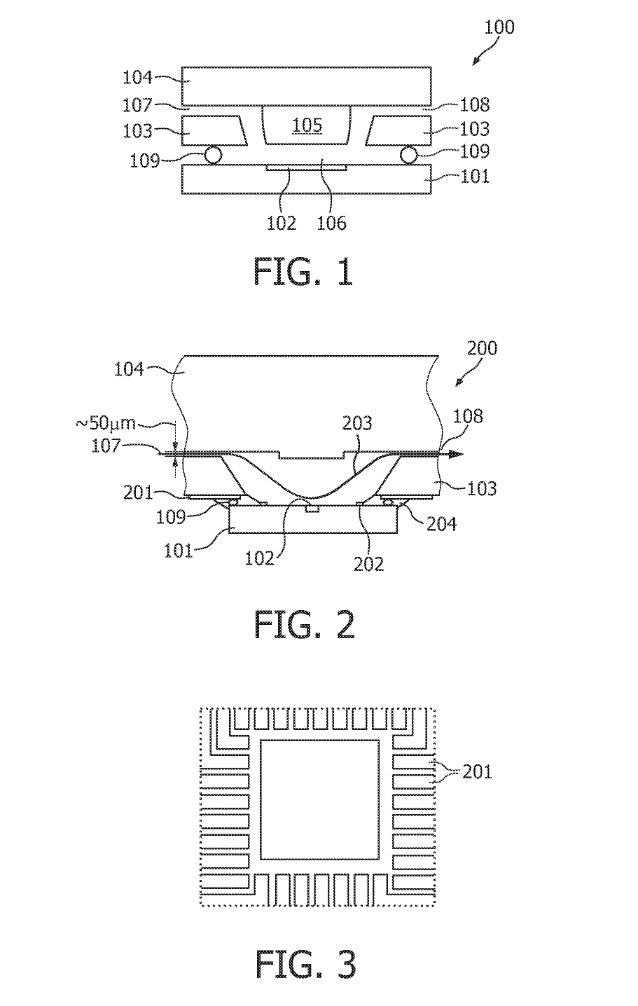

In the following, referring to FIG. 1, an electrochemical sensor device 100 for analyzing a biological sample according to an exemplary embodiment of the invention will be explained. FIG. 1 shows a cross-sectional view of the electrochemical sensor device 100.

The device 100 comprises an electronic chip 101 manufactured as a monolithically integrated chip in semiconductor technology, for instance in CMOS technology. The electronic chip 101 comprises a central sensor portion 102 being sensitive for particles of a sample, for instance being sensitive to specific DNA molecules which are complementary with respect to capture molecules which are immobilized on a surface of the sensor portion 102 (not shown in FIG. 1).

A carrier element comprising a well member 103 and a cover member 104 can be bonded to the electronic chip 101 via gold bumps 109 to fasten the well member 103 at the electronic chip 101 and to geometrically define a fluidic path together with the electronic chip 101. Such a fluidic path may be a trajectory along which a fluidic sample introduced in the device 100 will flow. In other words, between an inlet 107 and an outlet 108 of the electrochemical sensor device 100, a fluidic sample may flow and will be automatically brought in an interaction with the active sensor area 102 so that sensor events can be detected. A counter electrode 105 is provided as a part of the well member 103 and may abut against the cover member 104. This architecture may allow for a manufacture of the counter electrode 105 without a separate method step.

The well member 103 of the carrier element is a Moulded Interconnection Device (MID) and comprises a well 106. The sensor portion 102 is located adjacent to a bottom portion of the well 106.

The cover member 104 is a fluidic package part and is connected to the well member 103 by an adhering or gluing connection (not shown in FIG. 1). The fluidic package path 104 is arranged relative to the well member 103 to define the inlet 107 and the outlet 108 of the fluidic path between the cover member 104 and the well member 103.

Since the counter electrode 105 (which is made of Ag/AgCl) is arranged off the electronic chip 101, but is instead of this attached to the cover element 104, the sensor 100 can be manufactured with low cost.

FIG. 2 shows a conventional biosensor package 200 which comprises similar elements as the device 100, but lacks a counter electrode 105. Furthermore, gold-plated copper tracks 201 are shown which are connected via gold bumps 109 to an electronic chip 101. A flow barrier 202 is shown to prevent a flow of the fluidic sample flowing along a sample path 203 outside of the sensitive portion. An underfill 204 is provided to strengthen the bonding, and may be made of SU8 material. The flow barrier 202 may prevent underfill material 204 from flowing to the active area 102 of the chip.

FIG. 3 shows a plan view of such a conventional biosensor package 200.

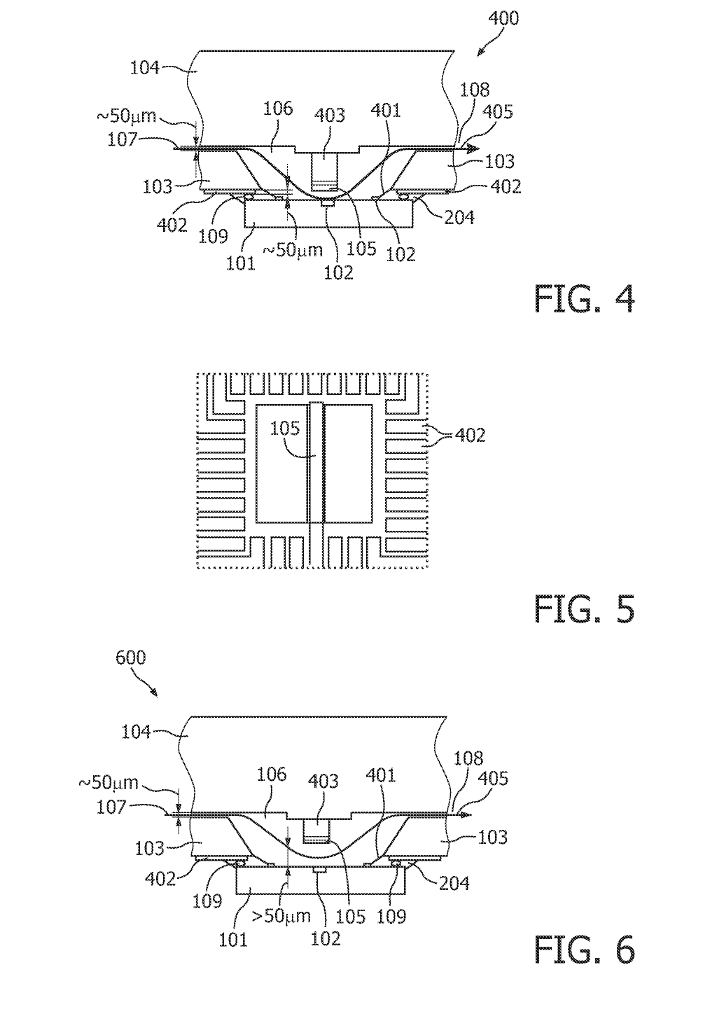

In the following, referring to FIG. 4, an electrochemical sensor device 400 according to an exemplary embodiment of the invention will be explained.

Again, an underfill 204 is shown which strengthens the bonding (and which may be made of SU8 material). A flow barrier 401 prevents underfill material 204 from flowing to the active area 102 of the electronic chip 101. Gold-plated copper tracks 402 are attached to a lower surface of the well element 103 and allow to transmit electronic signals such as detection signals from the electronic chip 101 via the bump 109 to an exterior circuitry. This may allow to address and read out the biochip 101 via the gold-plated copper tracks 402.

A bridge element 403 is shown which is part of the well member 103, abuts against the fluidic package part 104 and spaces the fluidic package part 104 with respect to the counter electrode 105. Therefore, a thin channel with a thickness of 50 μm is defined between the counter electrode 105 and the active surface 102 of the electronic chip 101. Also, the inlet 107 and the outlet 108 may have a dimension in the order of magnitude of 50 μm.

In FIG. 5, a plan view of the device 400 is shown, particularly the counter electrode 105 is shown as a silver comprising track. The fluidic channel defined by the geometry of the various components of the device 400 is denoted with reference numeral 405.

The embodiment shown in FIGS. 4 and 5 includes a MID bridge 403 extending into the well 106 of the MID 103.

In this embodiment, the counter electrode 105 is implemented on a tip of the bridge element 403. The MID opening or well 106, accommodates a MID bridge 403 on which the counter electrode 105 is fabricated. An Ag layer may be deposited on the counter electrode 105, for instance by means of electroplating or by applying an Ag ink. A liquid is forced to flow via the channel 405 that is approximately equal to the height of the Au bumps 109 (for instance 30 μm to 50 μm). When the biochip 101 is bonded on its carrier 103, 104, the counter electrode 105 is automatically correctly aligned with the fluidic path 405.

In the embodiment 600 shown in FIG. 6, a thinner or shorter MID bridge 403 is provided. In this embodiment, the fluidic channel 405 may be wider than in FIG. 4 to allow the liquid to reach the active area 102 of the biochip 101 more efficiently. This can be obtained by making the MID bridge 403 thinner, as shown in FIG. 6.

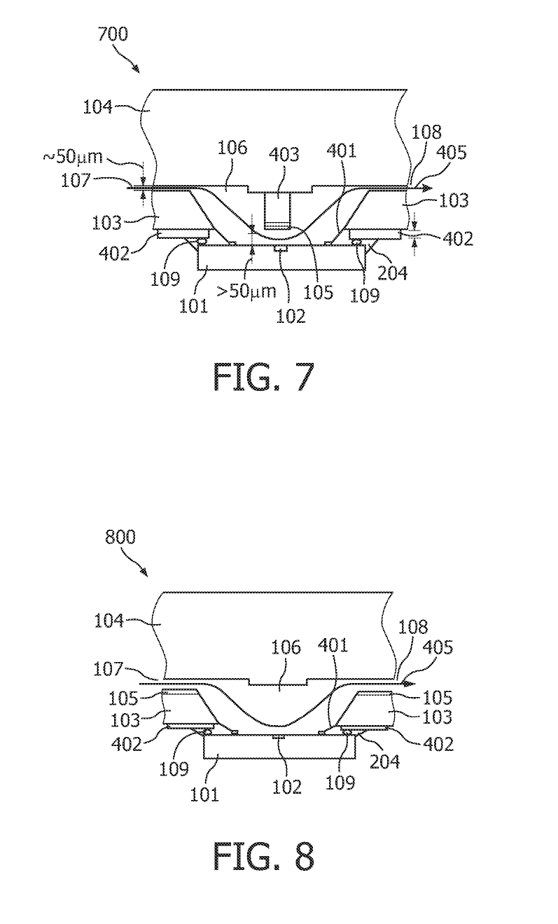

A sensor device 700 according to an exemplary embodiment of the invention shown in FIG. 7 is an embodiment in which a thicker MID track 103 is provided. The height of the MID element 103 may be approximately 500 μm. In another embodiment, the height may be 300 μm. The material of the underfill 204 may be epoxy.

As shown in FIG. 7, a wider fluidic channel 405 and a central portion close to the active area 102 can be obtained by making all the MID tracks 402 higher than the counter electrode track 105, see FIG. 7. Like in the embodiment of FIG. 6, the fluidic flow to the active area 102 of the biochip 101 may be more efficient.

In the following, referring to FIG. 8, a sensor device 800 according to an exemplary embodiment of the invention will be explained in which a double-sided carrier 103 will be explained.

The chip carrier 103, for instance a PCB (Printed Circuit Board), flex foil, etc., can also be implemented with tracks 105, 402 on both sides, see FIG. 8. In this case, the counter electrode 105 is located on the side of the fluidic channel 405 close to the inlet 107 and the outlet 108.

In the following, exemplary fields of application of exemplary embodiments of the invention will be explained. Embodiments of the invention can be applied to all kinds of electrochemical sensors.

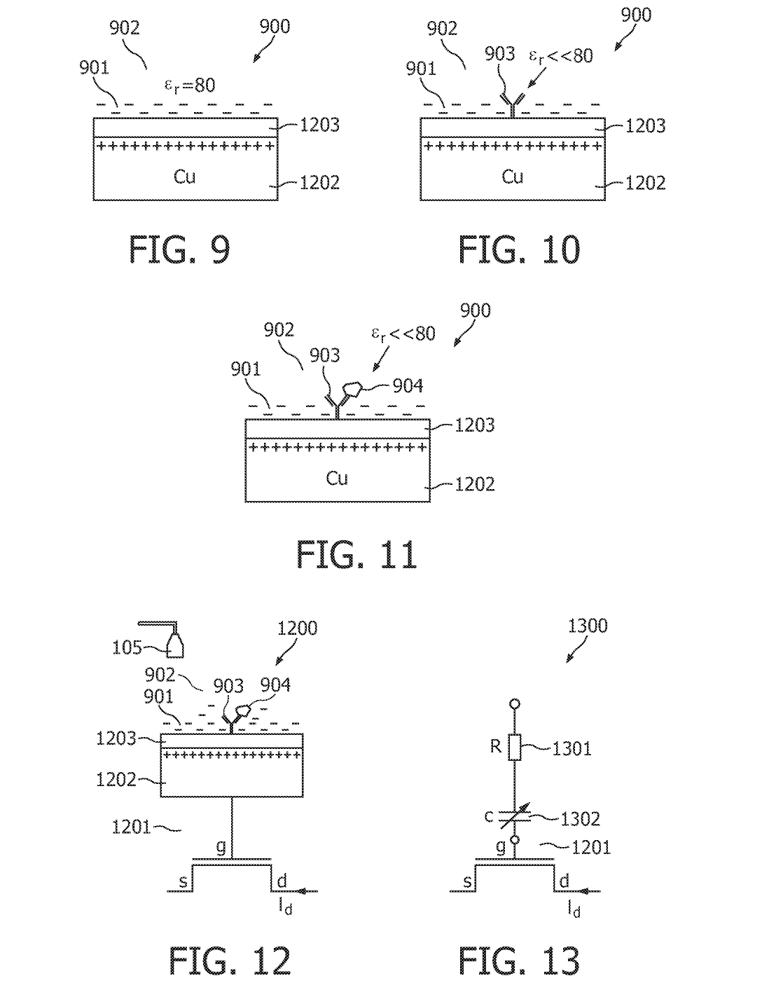

A single molecular biosensor may be based on a measurement of a change in an electrical double-layer capacitance at a solution-electrode interface, thereby forming a capacitive biosensor. An issue may be to provide a biosensor that is sensitive enough to detect a single biomolecule, hence the name single molecular biosensor. An embodiment of such a capacitive biosensor 900 is shown in FIG. 9 to FIG. 11.

As shown in FIG. 9, a working electrode 1202 (which may be made of copper material) is shown and is covered by a self-assembled monolayer (SAM) 1203. Above this, a double layer 901 may be formed. Above the layer 901, electrolytic salt water 902 is provided.

FIG. 9 shows an initialization mode, in which no biomolecule is present.

FIG. 10 shows the probe molecule 903 detection.

FIG. 11 shows the target molecule 904 detection.

As can be seen in FIG. 9 to FIG. 11, the relative permittivity ∈ᵣ significantly varies in the presence of the probe molecule 903, and in the presence of the target molecule 904.

The biosensing element comprises a self-assembled monolayer 1203 (SAM) on a top of a (semi)conductor electrode 1202 (for instance copper). The SAM 1203 may act as an immobilization layer that fixes probe molecules 903 (for instance antibodies or DNA molecules) to the electrode 1202. On top of the SAM 1203, an electrolyte 902, for instance salt water with a dielectric constant of ∈ᵣ=80 is applied.

In this configuration, a so-called diffused double layer (DL) 901 capacitance is formed at the interface between the electrolyte 902 and the SAM 1203. This state is depicted as the initial situation in FIG. 9.

The double layer capacitance changes when a probe molecule 903 attaches to the interface between the electrolyte 902 and the SAM 1203 (see FIG. 10) or when a specific target molecule 904 (for instance an antigen or a DNA molecule) binds to the probe molecule 903 (see FIG. 11). The capacitance change is a result of the decrease of the dielectric constant (∈ᵣ) of the double layer 901, because the dielectric constant of an organic material is usually much less than that of water. Finally, the capacitance change, which corresponds to the detection of a biomolecule 904, can be read out electrically (dielectric response signal).

FIG. 12 shows a bixel (biopixel) 1200, and FIG. 13 shows an equivalent electrical model 1300.

FIG. 12 shows the counter electrode 105 in contact with the electrolyte 902 and above the double layer 901 and the self-assembled monolayer 1203. Below the working electrode 1202, a MOSFET 1201 is connected. More particularly, the working electrode 1202 is connected to the gate connection g of the MOSFET 1201. Therefore, the conductivity between the source region s and the drain region d of the MOSFET 1201 is modulated in accordance with a sensor event. Therefore, when detecting a current I_{d} in response to an applied voltage between source s and drain d of the MOSFET 1201, a sensor result may be detected.

As can be seen in the equivalent electrical model 1300, the configuration of FIG. 12 corresponds to a serial connection of an ohmic resistance 1301 and a variable capacitance 1302 connected to the gate g of the MOSFET 1201.

Minimum feature sizes of advanced CMOS processes rapidly approach that of important biomolecules like DNA fragments and proteins. This may be considered as a unique opportunity to create novel products based on interfacing of silicon with biomolecules. The aim of the single molecular biosensor according to an exemplary embodiment of the invention is to measure the dielectric response signals of single biomolecules captured on the nanoelectrodes of a megabixel (biopixel) array. The addressing and readout of such a bioarray is comparable with that of a memory array, that is to say address lines may be used to identify the location of a row of bixels to be read from, while bit lines are used to read out the value of a row of bixels in parallel. A bixel and its equivalent electrical model are shown in FIG. 12 and FIG. 13.

By means of the sense MOS transistor (MOS) 1201, the capacitance change of the nanoelectrode 1202 as a result of the detection of a biomolecule 904 is converted into a drain current I_{d}. Next, the drain current I_{d} is converted into a voltage by a transimpedance amplifier (not shown) and further processed by readout electronics, that is to say pre- and post-processing electronics.

Such a single molecule biosensor can particularly open the way to the following attractive advantages for a biomolecular diagnosis:
High sensitivity: Sensitive to a single biomolecule
Label-free detection: No complex essay preparation
High measurement speed: bixels are read out in parallel.
Low cost: Standard CMOS process compatibility (integration)
Low power: Smart sensor architectures and design techniques can make the power consumption per bixel extremely low.

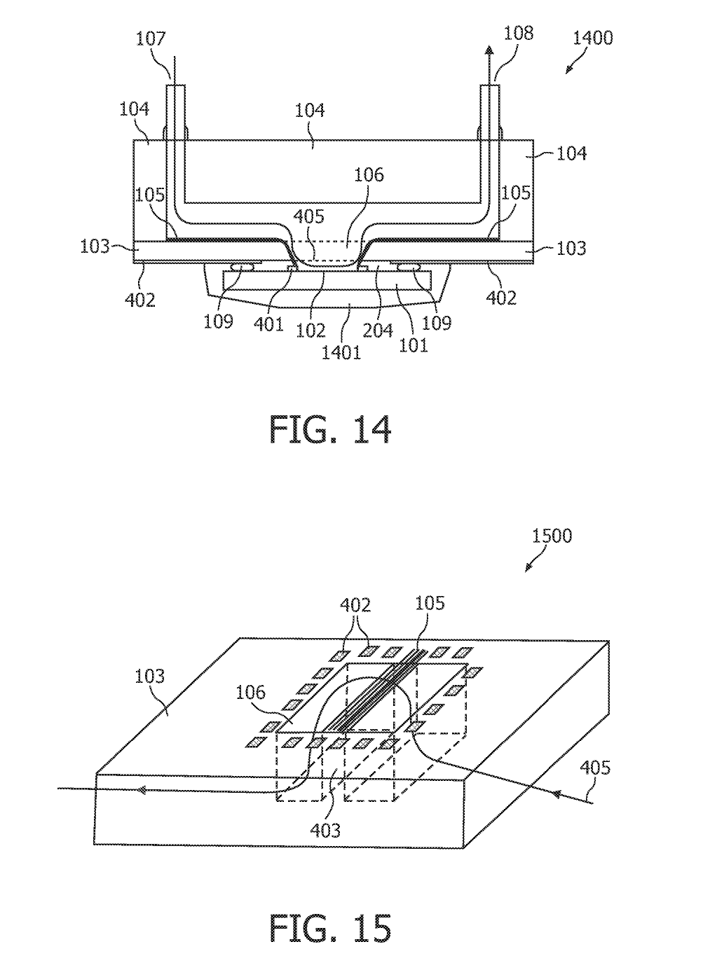

Next, referring to FIG. 14, an electrochemical sensor array 1400 according to an exemplary embodiment of the invention will be explained.

In the embodiment of FIG. 14, the counter electrode 105 is provided (for instance deposited) on an upper surface of the well plate 103. A resin zone 204 is shown as well as a SU8 flow barrier 401 and a resin environment 1401.

Furthermore, a fluid access hole 106 is shown.

FIG. 15 shows a schematic three-dimensional view 1500 of the MID element 103 of the embodiment of FIG. 4.

The view 1500 illustrates that the counter electrode 105 is formed as a part of the MID element 103.

It should be noted that the term “comprising” does not exclude other elements or features and the “a” or “an” does not exclude a plurality. Also elements described in association with different embodiments may be combined.

It should also be noted that reference signs in the claims shall not be construed as limiting the scope of the claims.

1. An electrochemical sensor device (100) for analysing a sample, the device (100) comprising
an electronic chip (101) comprising a sensor portion (102) being sensitive for particles of the sample;
a carrier element (103, 104) bonded to the electronic chip (101) to define a fluidic path together with the electronic chip (101);
a counter electrode (105) provided in a surface portion of the carrier element (103, 104).

2. The device (100) of claim 1,
wherein the carrier element (103, 104) comprises a well member (103), particularly a Molded Interconnection Device, comprising a well (106), wherein the sensor portion (102) is located adjacent to a bottom portion of the well member (103).

3. The device (100) of claim 2,
wherein the carrier element (103, 104) comprises a cover member (104), particularly a fluidic package part, arranged relative to the well member (103) to define an inlet (107) and an outlet (108) of the fluidic path between the cover member (104) and the well member (103).

4. The device (400) of claim 2,
comprising a sample flow barrier (401) between the well member (103) and the electronic chip (101).

5. The device (100) of claim 2,
wherein the well member (103) is bonded to the electronic chip (101).

6. The device (100) of claim 1,
wherein the carrier element (103, 104) is bonded to the electronic chip (101) via a metal bump (109), particularly for electrically coupling an electric circuit in the electronic chip (101) with an electric circuit conductively coupled to the carrier element (103, 104).

7. The device (400) of claim 1,
comprising an electrically conductive track (402) provided on a lower surface of the well member (103).

8. The device (100) of claim 2,
wherein the counter electrode (105) is accommodated in the well (106).

9. The device (400) of claim 2,
wherein the well member (103) comprises a bridge element (403) adjacent to the cover member (104) and extending in the well (106) towards the electronic chip (101), wherein the counter electrode (105) is formed at an end portion of the bridge element (403) to define the fluidic path between the counter electrode (105) and the sensor portion (102) of the electronic chip (101) opposing the counter electrode (105).

10. The device (800) of claim 3,
wherein the counter electrode (105) is accommodated in at least one of the group consisting of the inlet (107) and the outlet (108) of the fluidic path.

11. The device (800) of claim 3,
wherein the counter electrode (105) is connected to at least one of the group consisting of an upper surface of the well member (103) and a lower surface of the cover element (104) in at least one of the group consisting of the inlet (107) and the outlet (108) of the fluidic path.

12. The device (100) of claim 1,
wherein the counter electrode (105) is arranged off-chip.

13. The device (1200) of claim 1,
wherein the sensor portion (102) is a capacitive sensor portion, particularly comprises electric circuitry (1201) integrated in the electronic chip (101), a working electrode (1202) provided on the electric circuitry (1201), and a self-assembled monolayer (1203) provided on the working electrode (1202).

14. The device (100) of claim 1,
adapted as at least one of the group consisting of a sensor device, a biosensor device, a biochip, a lab-on-chip, an electrophoresis device, a sample transport device, a sample mix device, a cell lysing device, a sample washing device, a sample purification device, a polymerase chain reaction device, and a hybridization analysis device.

15. A sensor array for analysing a sample,
the sensor array comprising a plurality of electrochemical sensor devices (100) according to claim 1.

16. A method of manufacturing an electrochemical sensor device (100) for analysing a sample, the method comprising
providing an electronic chip (101) comprising a sensor portion (102) being sensitive for particles of the sample;
providing a carrier element (103, 104) bonded to the electronic chip (101) to define a fluidic path together with the electronic chip (101);
providing a counter electrode (105) in a surface portion of the carrier element (103, 104).
